(19) United States
(12) Patent Application Publication
(10) Pub. No.: US 2008/0020584 A1
(43) Pub. Date: Jan. 24, 2008

(54) Method of manufacturing semiconductor device and plasma processing apparatus

(76) Inventors: Shin Hirotsu, Nirasaki-Shi (JP); Yoshinori Suzuki, Nirasaki-Shi (JP)

Correspondence Address: Smith, Gambrell & Russell, Suite 800, 1850 M Street, N.W., Washington, DC, 20036, US

(21) Appl. No.: 11/725,559

(22) Filed: Mar. 20, 2007

Related U.S. Application Data
(60) Provisional application No. 60/792,976, filed on Apr. 19, 2006.

(30) Foreign Application Priority Data
Mar. 24, 2006 (JP) 2006-083649

(51) Int. Cl. H01L 21/302; C23F 1/00

(52) U.S. Cl. 438/725; 156/345.29; 257/E21.214

(57) ABSTRACT

The method of manufacturing a semiconductor device according to the present invention includes a step of etching an organic film formed to be embedded in recesses in a low dielectric constant film which is made of a material containing silicon, carbon, oxygen, and hydrogen. The organic film is typically a sacrifice film formed on the low dielectric constant film to be embedded in recesses formed in the low dielectric constant for embedding electrodes therein. The etching is performed with plasma of a process gas containing carbon dioxide. With the method, the organic film can be etched while suppressing damage to the low dielectric constant film.

### CROSS-REFERENCE TO RELATED APPLICATION

The present application claims priority from U.S. Provisional application No. 60/792,976 filed on Apr. 19, 2006, and the content of which is hereby incorporated by reference into this application.

### BACKGROUND OF THE INVENTION

1. Field of the Invention

The present invention relates to a technique for etching, by using plasma, an organic film that is formed to be embedded in a recessed portion in a film that has a low dielectric constant and includes silicon, carbon and oxygen.

2. Related Art

As a representative inter-layer insulating film for a semiconductor device, there is, for instance, a silicon dioxide film (SiO₂ film). However, recently, it is demanded to lower a specific dielectric constant of an inter-layer insulating film to satisfy the needs for a higher operating speed of a semiconductor device. Under the demands, now attentions are focused on a porous film containing silicon, carbon, oxygen, and hydrogen (described as “SiCOH” hereinafter). A specific dielectric constant of the SiO₂ film is around 4, while that of this SiCOH film is 2.7 or less. Since the SiCOH film has sufficient mechanical strength, the film is extremely effective as an inter-layer insulating film.

As a method of forming metal wiring, there has been known a technique for using a three-layered resist film and forming embedded wiring together with contact holes of viaholes by the dual damascene method. In the three-layered resist film, for instance, an organic film, an SOS film, and a photoresist film are laminated in this order from the bottom. The organic film is embedded in recessed portions for wiring or viaholes formed as a sacrifice film.

The sacrifice film embedded in the recessed portions is removed by etching and ashing. In this step, at first an etching gas is introduced for the SOG film into a processing chamber, and the SOG film is etched and removed by plasma of the etching gas. Then an etching gas for the organic film is introduced into the processing chamber. Then, the photoresist film, which is an organic-based film, and the organic film are etched simultaneously by the gas plasma. Then a film structure shown, for instance, in FIG. 8A is formed.

In FIG. 8A, reference numeral 10 denotes an insulating film; 11, an organic film embedded in the insulating film; 12, a copper wiring layer; 13, a stopper film; 14, an adhesive film; 15, a hard mask; and 16, an SOG film for forming a three-layered photoresist film. FIG. 8A illustrates a state in which a large portion of the organic film has been removed by etching, and the photoresist film 17 on the top of the resist film has also been removed by etching when the organic film 11 is etched.

In the conventional art, an oxygen-based (O₂) gas or an ammonia (NH₂)-based gas is used as an etching gas for the organic film 11. However, in the case where the porous SiCOH film is used as the insulating film, when an oxygen-based gas is used for etching, damage caused by the oxygen plasma becomes more serious. Furthermore, since the film is porous, the oxygen plasma intrudes into inside of the film, and a damaged layer 18 is formed on a surface of the insulating film 10 as shown in FIG. 8B, and a thickness of this damaged layer becomes larger.

When an ammonia-based gas is used, particles may be disadvantageously generated. Fluorine (F) is contained in the etching gas for the SOG film, and is deposited on a wall or other portions of the processing chamber. When an ammonia-based gas is introduced, the ammonia reacts with fluorine to generate an ammonium fluoride gas (NH₄F), which forms particles. Etching for the SOG film and that for the organic film 11 are performed in repetition in the same processing chamber, and a quantity of fluorine deposited in the container increases, which causes an increase in quantity of the particles.

JP-A-2000-353305 discloses a technique for using carbon dioxide gas plasma when etching an organic film while minimizing damage to a mask. However, this document does not include any description concerning the process of etching an organic film which is embedded in a porous SiCOH film and is a lowermost layer film in a multi-layered resist structure, nor the process of etching the organic film suppressing damage to the porous SiCOH film.

### SUMMARY OF THE INVENTION

The present invention was made in the light of the circumstances as described above, and an object of the present invention is to provide a technique for etching an organic film embedded in a recessed portion on a low dielectric constant film containing silicon, carbon, oxygen, and hydrogen while suppressing damage to the low dielectric constant film.

The present inventors investigated various gases as an etching gas for the organic film formed to be embedded in recesses on the low dielectric constant film containing silicon, carbon, oxygen, and hydrogen, namely, the porous SiCOH film. As a result, it was found that a gas containing carbon dioxide is suited to be used as the etching gas.

Accordingly, the present invention provides the following method of manufacturing a semiconductor device, and the method comprises the steps of:

(i) preparing an object to be processed, the object including a substrate, a low dielectric constant film that is formed on the substrate, having recesses, being made of a material containing silicon, carbon, oxygen, and hydrogen, and an organic film formed on the low dielectric constant film so as to be embedded in the recesses; and

(ii) etching the organic film of the object by plasma of a process gas containing carbon dioxide.

The process gas may further contain a nitrogen gas. It is preferable that the low dielectric constant film has a dielectric constant of 2.7 or less.

The present invention also provides a plasma processing apparatus for etching an object to be processed, the object including a substrate, a low dielectric constant film formed on the substrate, having recesses, being made of a material containing silicon, carbon, oxygen, and hydrogen, and an organic film formed on the low dielectric constant film so as to be embedded in the recesses, the plasma processing apparatus comprising: a processing chamber; a lower electrode which is placed in the vacuum chamber and on which the object to be processed is mounted; an upper electrode opposite to the lower electrode; a gas supply system for supplying a process gas containing carbon dioxide, the process gas being used to etch an organic film of the object to be processed; and a high-frequency power supply for applying high-frequency power between the lower electrode and the upper electrode for converting the process gas into plasma.

The gas supply system may supply a process gas further containing a nitrogen gas.

Typically, the recesses of the low dielectric constant film are used to embed electrodes, and the organic film is a sacrifice film formed on the low dielectric constant film so as to be embedded in the recesses for embedding electrodes. For instance, the recesses are viaholes for embedding electrodes for connecting both wiring of an upper layer and a lower layer in a multi-layer wiring structure and the organic film constitutes a bottom layer in a resist structure with a plurality of layers.

In addition, the present invention provides a computer-readable storage medium, in which a control program for performing the method of manufacturing a semiconductor device in the plasma processing apparatus.

With the present invention, the organic film is formed on the low dielectric constant film containing silicon, carbon, oxygen, and hydrogen so as to be embedded in the recesses, which is etched by plasma of the process gas containing carbon dioxide. Thus, the organic film can be etched while suppressing damage to the low dielectric constant film.

Specifically, when converting a process gas containing the carbon dioxide to plasma, carbon dioxide ions are produced. The carbon dioxide ions react with carbon in the organic film, which enables etching of the organic film. In contrast, the carbon dioxide ions hardly react with the low dielectric constant film, which makes it difficult to break a chemical bond between silicon and carbon in the low dielectric constant film. Because of the reasons, even when the organic film is etched by the plasma of the process gas containing carbon dioxide, damage to the low dielectric constant film can be suppressed.

### BRIEF DESCRIPTION OF THE DRAWINGS

FIG. 1 is a cross-sectional view illustrating a object to be processed used in an embodiment of the present invention;

FIG. 2A is a cross-sectional view illustrating the object to be processed immediately before formation of an organic film;

FIG. 2B is a cross-sectional view illustrating the object to be processed immediately after formation of the organic film;

FIG. 3 is a cross-sectional view illustrating a plasma processing apparatus according to an embodiment of the present invention;

FIG. 4 is a cross-sectional view of the object to be processed in steps (a) to (c) in a method of manufacturing a semiconductor device according to the present invention;

FIG. 5 is a cross-sectional view illustrating the object to be processed in steps (d) to (g) in a method of manufacturing a semiconductor device according to the present invention;

FIG. 6A is a view illustrating a chemical structure of an SiCOH film exposed to carbon dioxide ions (CO₂⁺);

FIG. 6B is a view illustrating a breakage of an Si—C bond in the SICOH film by oxygen radicals (O*);

FIG. 7A is a view illustrating a cross-sectional form around a viahole on a wafer having been subjected to an etching process according to the present invention;

FIG. 7B is a view illustrating a cross-sectional view of an area with no viahole in the wafer having been subjected to the etching process according to the present invention;

FIG. 8A is a cross-sectional view illustrating a laminated structure used in a process of manufacturing a semiconductor device; and

FIG. 8B is a cross-sectional view illustrating formation of a damaged layer due to etching of the laminated structure shown in FIG. 8A.

### DETAILED DESCRIPTION OF THE PREFERRED EMBODIMENTS

A object to be processed used in an embodiment of the present invention has a semiconductor wafer as a substrate, a low dielectric constant film formed on the wafer and having recessed portions, and an organic film embedded in recessed portions of the low dielectric constant film. For convenience in description below, the entire object to be processed is referred to as “wafer”. The low dielectric constant film is made of a material including silicon, carbon, oxygen, and hydrogen. A porous SICOH film having the dielectric constant of 2.7 or below can be used as the low dielectric constant film. It is to be noted that the higher a percentage of void in this SICOH film, the larger the dielectric constant is.

A process of etching an organic film formed to be embedded in the recessed portions of a porous SICOH film is described below with reference to the case where wiring is formed using a plurality of a multilayered resist structure by the dual damascene method.

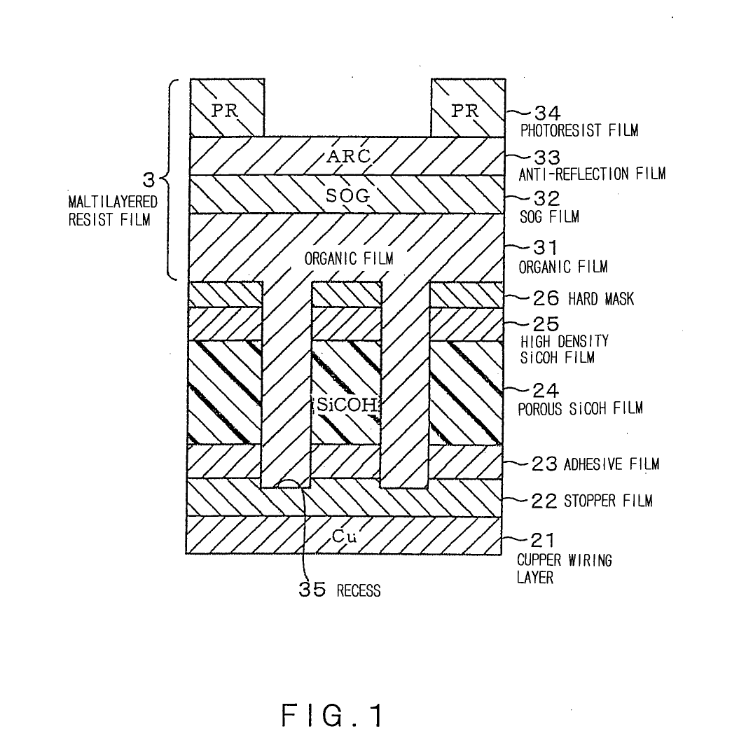

FIG. 1 is a view illustrating a structure including an organic film formed to be embedded in recessed portions of a porous SICOH film. In FIG. 1, the reference numeral 21 denotes a wiring layer as a lower layer made of, for instance, copper, while reference numeral 22 denotes a stopper film for preventing the copper wiring layer from being etched, which is, for instance, an SiCN film or a SIC film having a thickness of 35 nm. Reference numeral 23 denotes a adhesive film for improving adhesion with the stopper film 22 and having a thickness of, for instance, 30 nm. The adhesive film is, for instance, an SiO₂ film or a TiN film, and also has a complementary function for the stopper film 22.

In FIG. 1, reference numeral 24 denotes a porous SiCOH film functioning an insulating film formed with a thickness of 540 nm, and reference numeral 25 denotes a hard mask comprising an SiCOH film having high density. The high density SiCOH film 25 is a film having the specific dielectric constant K larger than 2.7 and not more than about 3.5 (2.7<K≦3.5). In FIG. 1, reference numeral 25 denotes a hard mask comprising, for instance, an SiO₂ film formed with the thickness of 50 nm. The high density SiCOH film or the hard mask 26 functions as a cap film for the porous SiCOH film 24. When the porous SiCOH film 24 is protected, either one of the high density SiCOH film 25 or the hard mask 26 may be eliminated.

In FIG. 1, reference numeral 31 denotes an organic film (OF) formed with the thickness of 300 nm, while reference numeral 32 is an SOG film formed with the thickness of 80 nm and functioning as a hard mask. The SOG film as used herein represents an SiO₂ film formed by the SOG (Spin On Glass) method. In FIG. 1, reference numeral 33 denotes an anti-reflection film (ARC film) formed with the thickness of, for instance, 90 nm, and comprises an organic film. Furthermore, in FIG. 1, reference numeral 34 denotes a photoresist film formed with the thickness of, for instance, 250 nm. In this embodiment, the multilayered resist structure 3 is formed with the organic film 31, the SOG film 32, the anti-reflection film 33, and the photoresist film 34, and the organic film 31 is a lowermost layer film of the multilayered resist structure 3. There is no specific restriction over the multilayered resist structure 3 so long as the organic film 31, the SOG film 32, and the photoresist film 34 are laminated from the lower side in the order described above, and when the anti-reflection capability of the SOG film 32 is sufficient, the anti-reflection film 33 is not necessary.

The organic film 31 is made of an organic material such as CT (Carbon Toshiba produced by JSR Corp.). The organic film 31 is embedded as a sacrifice film in recessed portions for embedding an electrode therein which is formed on the porous SiCOH film. In this example, the recessed portions 35 are formed to be a groove (trench section) for embedding a copper wiring layer which is an upper layer in the multi-layered wiring structure and a viahole for embedding an electrode for connection between the upper copper wiring layer and the lower copper wiring layer 21.

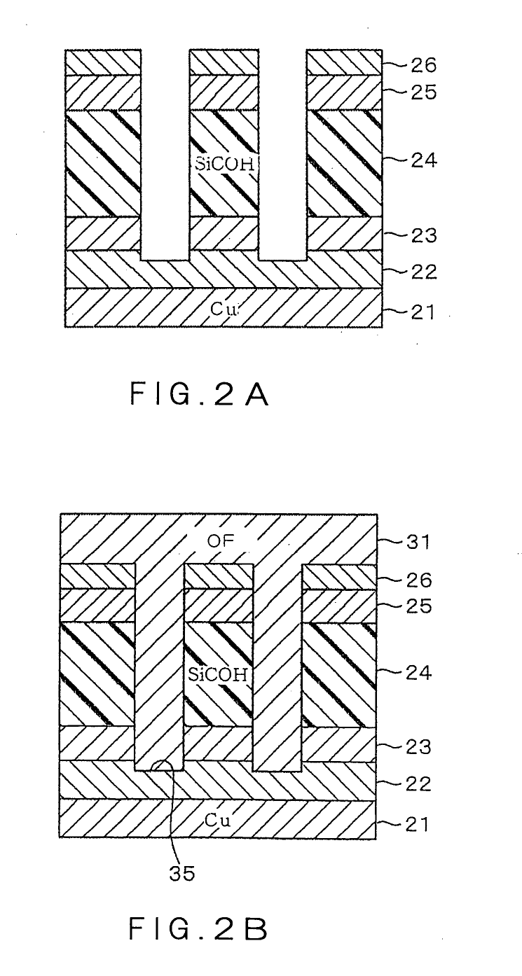

The film structure as described above is formed, for instance, as described below. At first, as shown in FIG. 2A, the copper wiring layer 21, the stopper film 22, the adhesive film 23, the porous SiCOH film 24, the high density SiCOH film 25, and the hard mask 26 are laminated from the bottom in this order each with a predefined thickness. Then, the recessed portions 35 used for formation of a viahole or the like are formed by etching. Then, as shown in FIG. 2B, the organic film 31 is formed to be embedded in the recessed portions 35 in the structure shown in FIG. 2A. Then, the SOG film 32 and the anti-reflection film 33 are formed in this order from the lower side on the organic film 31, and finally the photoresist film 34 having a predefined form is formed to obtain the structure shown in FIG. 1.

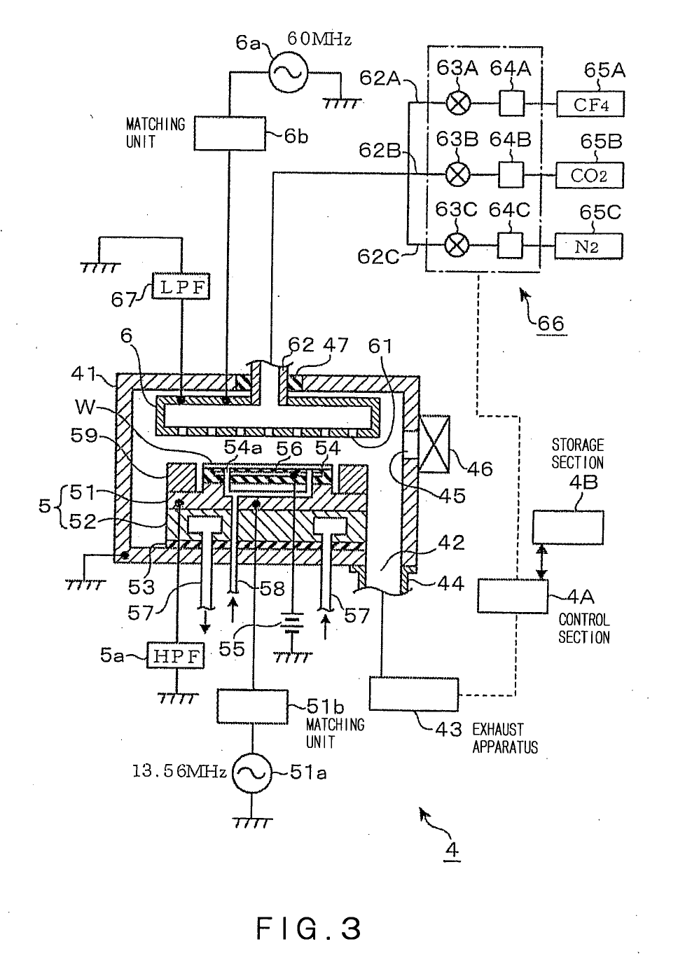

Then, an example of a plasma processing apparatus for performing the method for manufacturing the semiconductor device according to the present invention is described with reference to FIG. 3.

The plasma processing apparatus 4 shown in FIG. 3 comprises a vacuum processing chamber 41 having a sealed space inside thereof, a mounting base 5 provided at a center of a bottom surface inside the processing chamber 41, and an upper electrode 6 provided above the mounting base 5 and facing the mounting base 5.

The processing chamber 41 is electrically grounded, and an exhaust apparatus 43 is connected via an exhaust pipe 44 to an exhaust port 42 on a bottom surface of the processing chamber 41. A pressure adjusting section (not shown) is connected to the exhaust apparatus 43, and configured to maintain a desired vacuum degree by vacuuming the inside of the processing chamber 41 according to a signal from a control section 4A described herein after. A transfer port 45 for a wafer W is provided on a wall surface of the processing chamber 41, and can be opened and closed by a gate valve 46.

The mounting base 5 comprises a lower electrode 51 and a support body 52 for supporting the lower electrode from the lower side, and is provided via an insulating member 53 on a bottom surface of the processing chamber 41. An electrostatic chuck 54 is provided on a top of this mounting base 5, and a wafer W is mounted on the mounting base 5 via this electrostatic chuck 54. This electrostatic chuck 54 comprises an insulating material, and electrode foil 56 connected to a high voltage current power source 55 is provided inside the electrostatic chuck 54. When a voltage is applied to the electrode foil 56 from the high voltage current power source 55, the wafer W is electrostatically sucked to the electrostatic chuck 54. Provided on the electrostatic chuck 54 is a through-hole 54a for discharging a back-side gas described hereinafter to a space above this electrostatic chuck 54.

A flow path 57 for a prespecified cooling medium (for instance, a fluorine-based fluid, or water well known in the prior art) is provided in the mounting base 5. When this cooling medium flows through the cooling medium flow path 57, the mounting base 5 is cooled, and the wafer W mounted on the mounting base 5 is cooled to a desired temperature. Furthermore, a temperature sensor (not shown) is mounted on the lower electrode 51, and a temperature of the wafer W on the lower electrode 51 is always monitored by this temperature sensor.

A gas flow path 58 is formed for supplying a thermally conductive gas such as a He (helium gas) as a back-side gas is formed in the mounting base 5, and the gas flow path 58 is opened on a top surface of the mounting base 5. The openings are communicated to through-holes 54a provided on the electrostatic chuck 54. When a back-side gas is supplied to the gas flow path 58, the back-side gas flows to a space above the electrostatic chuck 54 via the through-holes 54a. When this back-side gas homogeneously spreads in a space between the electrostatic chuck 54 and the wafer W placed on the electrostatic chuck 54, the thermal conductivity in the space is improved.

The lower electrode 51 is grounded via a by-pass filter (HPF) 5a, and a power source 51a for a high frequency power with the frequency of, for instance, 13.56 MHz is connected via a matching unit 51b. A focusing ring 59 is provided around an outer periphery of the lower electrode 51 to surround the electrostatic chuck 54, so that plasma is focused on the wafer W on the mounting base 5.

The upper electrode 6 is hollow, and a number of pores 61 for spreading and distributing a process gas into the processing chamber 41 are formed on a bottom surface thereof each as a gas shower head. Furthermore, a gas inlet pipe 62 is provided at a center of a top surface of the upper electrode 6, and this gas inlet pipe 62 penetrates the top surface of the processing chamber 41 at the center thereof via an insulating member 47. This gas inlet pipe 62 is branched to three branch pipes to form branch pipes 61A to 62C. The branch pipes 62A to 62C are connected to gas supply sources 65A to 65C via valves 63a to 63C and flow rate controllers 64A to 64C to the gas supply sources 65A to 65C respectively. The valves 63A to 63C and the flow rate controllers 64A to 64C form a gas supply control system 66 for providing controls over gas supply from the gas supply sources 65A to 65C according to control signals from a control section 4A described below. In this embodiment, the gas supply sources 65A, 65B, and 65c are supply sources for CF₄ gas, CO₂ gas, and N₂ gas. A gas supply system for supplying a process gas containing carbon dioxide and nitrogen gas is formed mainly with gas supply sources 65B, 65C, valves 63B, 63C, and flow rate controllers 64B, 64C.

The upper electrode 6 is grounded via a low-pass filter (LPF) 67. A high frequency power source 6a with a frequency of, for instance, 60 MHz higher than a frequency of the high frequency power 51a is connected to the upper electrode 6 via a matching unit 6b. A high frequency power from the high frequency power supply source 6a connected to the upper electrode 6 is used for converting the processing gas to plasma. A high frequency power from the high frequency power source 51a connected to the lower electrode 51 is used for implanting ions present in the plasma onto a surface of the wafer W by applying a bias power to the wafer W. The high frequency power sources 6a, 51a are connected to the control section 4A for controlling powers supplied to the upper electrode 6 and the lower electrode 51 according to a control signal respectively.

The control section 4A provided in the plasma processing apparatus 4 comprises a computer having a control program, a memory, and a CPU. The program includes commands for carrying out plasma process to the wafer W by executing the steps described hereinafter by sending control signals to each section in the plasma processing apparatus 4 from the control section 4A. The memory has a space in which parameter values for a pressure, a period of time, a gas flow rate, a power and the like employed in the processing are written. When the CPU executes each command in the program, the processing parameters are read out from the memory, and control signals corresponding to the parameter are sent to each section of the plasma processing apparatus 4. The programs (including programs relating to operations for inputting the processing parameters and relating to displays) are stored in a computer-readable storage medium 4B such as a flexible disk, a compact disk, or an MO (magneto-optical disk), and is installed in the control section 4A.

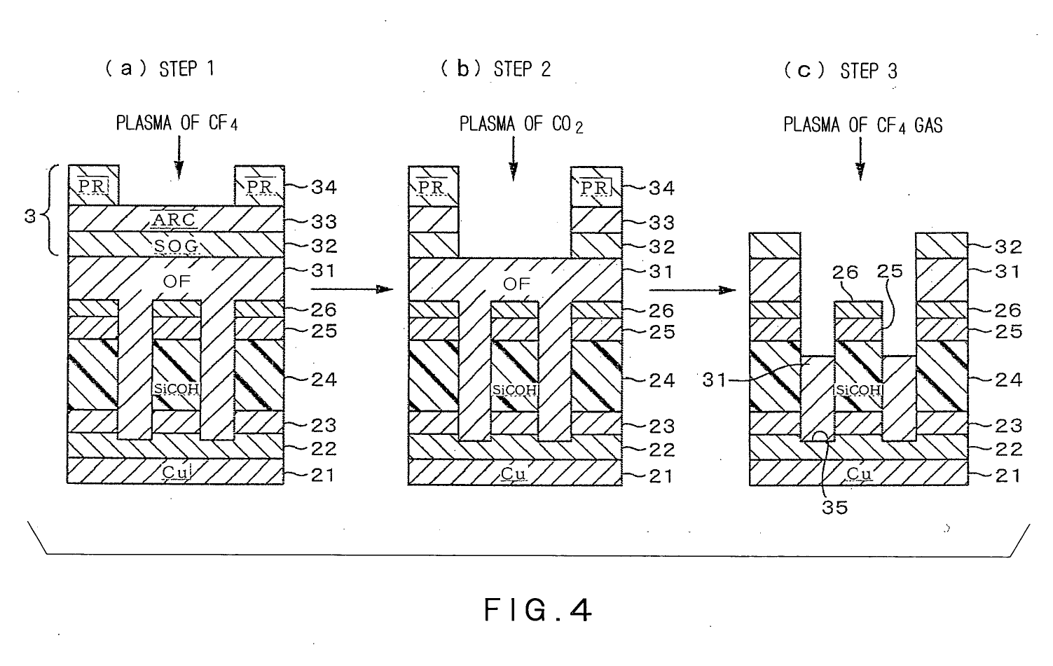

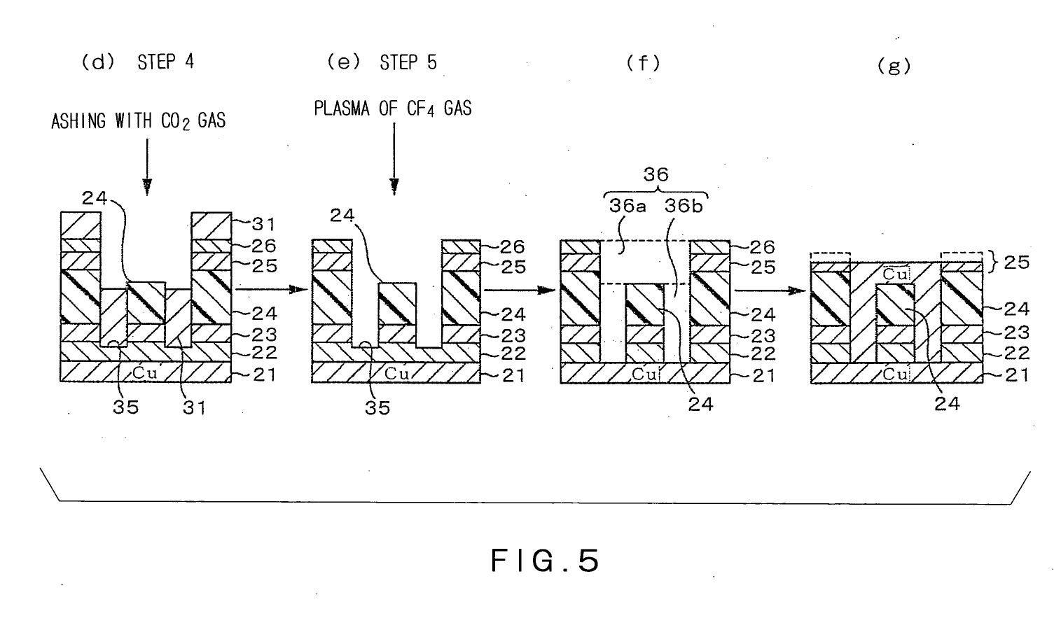

Next a method of manufacturing a semiconductor device according to an embodiment of the present invention is described with reference to FIG. 4 and FIG. 5. The plasma processing apparatus 4 is used in the embodiment.

At first a gate valve 46 is opened, and the wafer W with a size of 300 mm (12 inches) is carried into the processing chamber 41 by a carrier mechanism not shown. The wafer W has the film structure shown in FIG. 1 and FIG. 4(a). After the wafer W is placed on the mounting base 5, the wafer W is sucked to the mounting base 5 electrostatically. Then the carrier mechanism is retarded from the processing chamber 41, and the gate valve 46 is closed. Then a back-side gas is supplied through gas flow path 58, and the wafer W is cooled down to a predefined temperature. Then the following steps 1 to 5 are carried out.

Step 1 Etching of the Anti-Reflection Film and the SOG Film

The processing chamber 41 is evacuated by the exhaust apparatus 43 to generate vacuum inside the processing chamber 41 at a desired degree which is, for instance, 13.3 Pa (100 mTorr). Then a CF₄ gas is supplied to inside of the processing chamber 41 for 90 seconds at a flow rate of 150 sccm. On the other hand, a high frequency power with the frequency of 60 MHz and a unit power of 300 W/70685.8 mm² (an area of the 300 mm wafer) obtained by dividing the power by an area of the substrate (simply referred to as power hereinafter) is supplied to the upper electrode 6 to generate plasma of the CF₄ gas. At the same time, a high frequency power with the frequency of 13.56 MHz is supplied to the lower electrode with the power of 500 W/70685.8 mm².

The CF₄ gas plasma includes active species of compounds with carbon (C) and fluorine (F). Then the SiO₂ film constituting the anti-reflection film 33 or the SOG film 32 is exposed to the active species, the films react with atoms in the films to generate chemical compounds. As shown in FIG. 4(b), the anti-reflection film 33 and the SOG film 32 are etched successively. Etching is performed by adjusting conditions for etching such as a flow rate of the process gas, the etching time and the like, and the etching operation is finished when the anti-reflection film 33 and the SOG film 32 are completely etched.

In this step, the anti-reflection film 33, the photoresist film 34, and the organic film 31 have high etching selectivity relative to active species of the compounds between carbon and fluoride, and the etching speed is lower than that in the SOG film 32. A thickness of the photoresist film 34 is 250 nm, that of the anti-reflection film 33 is 90 nm, and that of the SOG film 32 is 80 nm. Because of the configuration, the photoresist film 34 remains after etching for the anti-reflection film 33 and the SOG film 32 is completed.

Step 2 Etching for the Photoresist Film, the Anti-Reflection Film, and the Organic Film

Then inside of the processing chamber 41 is evacuated by the exhaust apparatus 43 to remove the CF₄ gas still remaining in the processing chamber 41. Then CO₂ gas and N₂ gas are supplied for 55 seconds at flow rates of 400 sccm and 100 sccm respectively each as a process gas into the processing chamber 41. On the other hand, the process gas containing the carbon dioxide gas and the nitrogen gas is turned into plasma by supplying a power of 1000 W/70685.8 mm² to the upper electrode 6. At the same time, a high frequency power with the frequency of 13.56 MHz is supplied to the lower electrode 51 with the power of 750 W/70685.8 mm².

A substantial portion of the process gas plasma containing the carbon dioxide gas and the nitrogen gas comprises carbon dioxide ions (CO₂⁺). Therefore, the reaction expressed by the following formula (1) proceeds and etching is performed in the photoresist film 34, the anti-reflection film 33, and the organic film 31:
CO₂⁺+C→2CO (1)

Because of the reaction, the photoresist film 34, the anti-reflection film 33, and the organic film 31 are etched as shown in FIG. 4(c). In this step, the organic film 31 embedded in the recessed portion 35 is not etched and left as it is by adjusting the conditions for etching such as a process gas supply rate, and a time for the etching.

The carbon dioxide ions hardly react with the SiO₂ film, and therefore the SiO₂ film is hardly etched by plasma of the CO₂ gas. Therefore, the SOG film (SiO₂ film) 32 which is a layer below the anti-reflection film 33, and the hard mask 26 (SiO₂ film) 32 each function as a mask.

Step 3 Process for Etching of the Hard Mask and the SiCOH Film

Then inside of the processing chamber 41 is evacuated by the exhaust apparatus 43 to remove the CO₂ gas and the N₂ gas remaining in the processing chamber 41. Then, while a space inside the processing chamber 41 is maintained at a predefined vacuum degree, the CF₄ gas is supplied at a predefined flow rate. At the same time a high frequency power with the frequency of 60 MHz is supplied to the upper electrode 6 to turn the CF₄ gas into plasma, and also a high frequency power with the frequency of 13.56 MHz is supplied to the lower electrode 51.

As described above, the SiO₂ film constituting the hard mask 26, the high density SiCOH film 25, and the porous SiCOH film 24 are etched with the plasma of the CF₄ gas as shown in FIG. 5(d). In this step, the etching conditions such as a supply rate of the process gas or the etching time are adjusted so that the porous SiCOH film is etched with a predefined depth.

In this step, also the SOG film 32 is etched and removed by the CF₄ gas plasma. As described above, the CF₄ gas plasma hardly reacts with an organic film, and therefore the etching speed in the organic film 31 below the SOG film 32 or the organic film 31 embedded in the recessed portion 35 is extremely slow, so that the organic film 31 functions as a mask.

Step 4 Process for Ashing an Organic Film

Then inside of the processing chamber 41 is exhausted by the exhaust apparatus 43 to remove the CF₄ gas remaining there. Then, while the inside of the processing chamber 41 is maintained at a predefined vacuum degree, the CO₂ gas is supplied at a predefined flow rate. On the other hand, a high frequency power with the frequency of 60 MHz is supplied to the upper electrode 6 to turn the CO₂ gas to plasma, and at the same time a high freuquency power with the frequency of 13.56 MHz is supplied to the lower electrode 51. Ashing is performed with the CO₂ gas plasma as described above, and then the organic film 31 which is an upper layer of the hard mask 26 and the organic film 31 embedded in the recessed portion are turned into ash and removed, as shown in FIG. 5(e).

In this step, the reaction as expressed by the formula (1) proceeds in the photoresist film 34, or the organic film 31 because of the carbon dioxide ions generated due to the CO₂ gas plasma, and ashing is performed to the films. On the other hand, the SiO₂ film is hardly etched by the carbon dioxide ions, and therefore the hard mask (SiO₂ film) 26 below the organic film 31 remains. The ashing process may be performed by using other ashing device not shown.

Step 5 Process for Etching a Stopper Film

When the step 4 is performed by using another ashing device, the wafer W is again returned to the plasma processing apparatus shown in FIG. 3. Then, preserving inside of the processing chamber 41 at a predefined vacuum degree, the CF₄ gas is supplied into the processing chamber 41 at a predefined flow rate. On the other hand, a high frequency power with the frequency of 60 MHz is supplied to the upper electrode 6 to turn the process gas to plasma, and also a high frequency power with the frequency of 13.56 MHz is supplied to the lower electrode 51.

The SiC film (or an SiCN film) constituting the stopper film 22 is etched with the CF₄ gas plasma as shown in FIG. 5(f). A thickness of the stopper film 22 is 35 nm, while a thickness of the hard mask (SiO₂ film) 26 is 50 nm, and therefore also the hard mask 26 is etched by the CF₄ plasma. However, by controlling the etching conditions such as a supply rate or the process gas or the etching period of time so that etching is finished at the point of time when the stopper film 22 is etched, it is possible to remain the hard mask 26. Step 5 may be performed with an etching apparatus, instead of the plasma processing apparatus used in steps 1 and 2.

By carrying out the steps 1 to 5 described above, the structure as shown in FIG. 5(f) is obtained. A metal, for instance, copper is embedded in a recessed portion 36 prepared as described above, and then the embedded copper is flattened by the CMP (Chemical Mechanical Polishing) process until a thickness of the high density SiCOH film is reduced to a half of the original thickness. With this operation, as shown in FIG. 5(g), a viahole 36b connecting a wiring layer 36a which is an upper layer and the wiring layer 21 below the wiring layer 36a is formed simultaneously.

In the method described above, the organic film 31 embedded in the porous SiCOH film 24 is etched by plasma of the process gas containing the carbon dioxide gas. Because of this method, the organic film 31 can be etched suppressing damage to the porous SiCOH film 24 during the etching process. The reason is as described below.

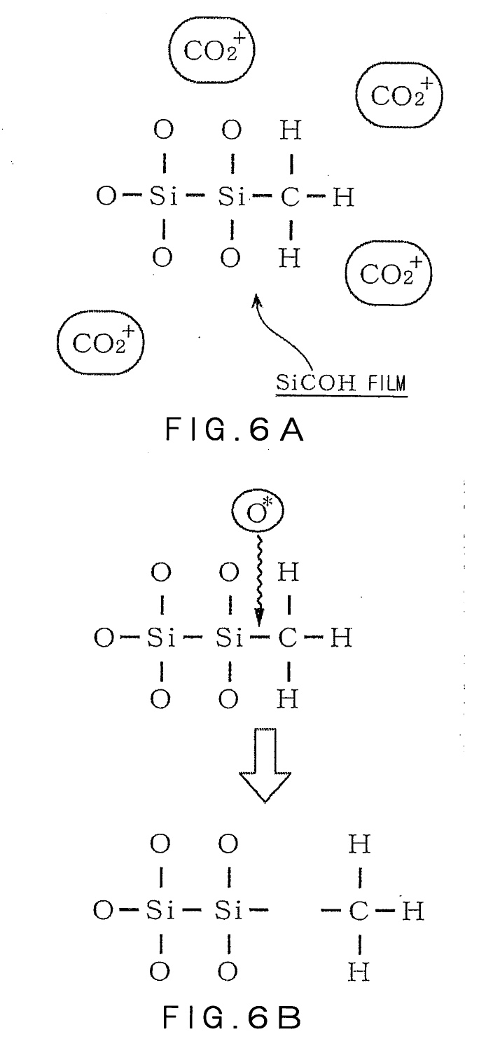

A main component of the SiCOH film has a chemical structure as shown in FIG. 6A, and a methyl group (—CH₃) is bonded to silicon.

When the carbon dioxide gas is turned into plasma, most of the carbon dioxide gas is turned into the carbon dioxide gas ions (CO₂⁺). The carbon dioxide gas ions hardly react with the methyl group bonded to silicon, and therefore the Si—C bond between silicon and carbon in the methyl group is hardly broken. Therefore, since the porous SiCOH film 24 hardly reacts with the carbon dioxide gas plasma. As a result, the porous SiCOH film 24 is little damaged. Because of the feature, only the organic film 31 embedded in the porous SiCOH film 24 is electively etched. What is described above is also true for the ashing process described above.

An oxygen gas used as an etching gas in the conventional technology generates oxygen radicals (O*) when turned into plasma. For instance, as shown in FIG. 6B, the oxygen radicals easily react with the methyl group bonded to silicon, and breaks the Si—C bond. Because of the feature, the oxygen plasma denatures the porous SiCOH film 24. Therefore, when the organic film 31 embedded in the porous SiCOH film 24 is etched, also the porous SiCOH film 24 is denatured, so that damage to the porous SiCOH film 24 are serious.

When the porous SiCOH film 24 is seriously damaged, the specific dielectric constant becomes higher. This deteriorates the electric performance of the device. Furthermore a methyl group is bonded to silicon in the porous SiCOH film 24 as described above, and the methyl group is hydrophobic, so that also the film is hydrophobic. However, when the bond between silicon and the methyl group is broken, a hydroxyl group (—OH), which is hydrophilic, easily bond to silicon, so the film easily absorbs moisture. When the porous SiCOH film 24 absorbs moisture, insulation breakage easily occurs, which lowers the yield. Therefore, it is preferable to suppress damage to the porous SiCOH film 24 as much as possible.

When N₂ gas is contained in a process gas used for etching the organic film embedded in the porous SiCOH film 24, adjustment for a development line width can be performed. That is, when a quantity of the nitrogen gas in the process gas is appropriate, the nitrogen gas provides protection for side walls, and the development line width will becomes smaller. On the contrary, when a quantity of added nitrogen gas is large, the selectivity in etching for the SOG film 32 placed on the organic film 31 generally becomes lower. A quantity of nitrogen gas in the process gas can be reduced to around a half of the carbon dioxide gas. However, when a content of carbon in the organic film 31 becomes higher, the nitrogen gas is not required. Therefore, whether the nitrogen gas is contained in the process gas or not and the quantity may be decided according to a form of the recessed portion 35, components of the organic film 31, and the like.

In the process described above, particles are never generated. As described above, the material as a cause for generation of particles is ammonium fluoride generated as a product of reaction between the ammonia gas used for etching the organic film in the conventional technology and the CF₄ gas used for etching the SOG film 32 and the anti-reflection film 33. In the process described above, however, plasma of carbon dioxide gas is used for etching the organic film 31. The carbon dioxide ions obtained when the carbon dioxide is turned into plasma do not generate solid materials through reactions with carbon or fluorine generated by the CF₄ gas plasma, so that generation of particles is suppressed.

As described above, in a damascene process, the present invention is especially effective for etching the organic film 31 which is embedded as a sacrifice film in the recessed portion 35 of the porous SiCOH film 24 having a low dielectric constant and is provided as a lowermost layer for a multi-layered resist structure. That is, the damascene process includes a step of etching the organic film 31 embedded in the recessed portion 35 formed on the porous SiCOH film 24 constituting an inter-layer insulating film. In this step, when etching for the organic film 31 proceeds, the porous SiCOH film 24 adjoining the recessed portion 35 is exposed. In this case, since the porous SiCOH film 24 is exposed to the atmosphere for etching, it is necessary to select a process gas for etching which hardly reacts with the porous SiCOH film 24. From this point of view, it is effective and advantageous to use a process gas containing the carbon dioxide gas as described above.

It is necessary to use the porous SiCOH film 24 having a large void percentage for lowering the specific dielectric constant. When the percentage of void is high, plasma of the process gas intrudes into inside of the porous SiCOH film 24 during the process for etching the organic film 31, which causes serious damage. Therefore, suppression of damage to the porous SiCOH film 24 by using a process gas containing carbon dioxide hardly reacting with the porous SiCOH film 24 is especially effective and advantageous when the porous SiCOH film 24 is used as an inter-layer insulating film.

Furthermore, in the multi-layered resist structure, the SOG films 32 as an inorganic film are provided between the photoresist film 34 which is an organic film, the anti-reflection film 33, and the organic film 31, and the organic films and the inorganic films are etched alternately. That is, when the SOG film 32, which is an inorganic film, is etched, the organic films (the photoresist film 34, the anti-reflection film 33, and the organic film 31) function each as a mask. When any the photoresist film 34, the anti-reflection film 33, and the organic film 31 is etched, the inorganic film (SOG film 32) functions as a mask.

For the reasons as described above, it is necessary to select a gas, which hardly reacts with the inorganic SOG film 32 and does not generates solids (particles) through a reaction with a process gas used for etching inorganic films, as a process gas for etching the organic films. Also from this point of view, it is effective to use a process gas containing carbon dioxide for etching the organic film 31.

For the reasons as described above, the process gas used for etching the organic film 31 embedded in the porous SiCOH film 24 is required only to containing carbon dioxide. That is, it is allowable to use only carbon dioxide gas or a gas containing the carbon dioxide gas and the nitrogen gas. Furthermore, a mixture gas of carbon dioxide gas and other gases such as carbon monoxide gas, argon gas, or helium gas may be used.

The present invention can be applied to any method of manufacturing a semiconductor device including a step of etching the organic film 31 embedded in a recessed portion of the porous SiCOH film 24. For instance, when the organic film 31 is embedded in the recessed portion 35 for embedding an electrode formed on the porous SiCOH film 24, the recessed portion may be a viahole for embedding an electrode for connection between an upper wiring layer and a lower wiring layer in the multi-layered wiring structure. That is, it is not always necessary to form wiring and a viahole by the damascene method.

### EXPERIMENT EXAMPLE 1

The film structure shown in FIG. 1 was formed on a wafer W, and the organic film 31 embedded in the porous SiCOH film 24 was etched by using the plasma processing apparatus shown in FIG. 3 and according to the conditions for step 1 and step 2 above.

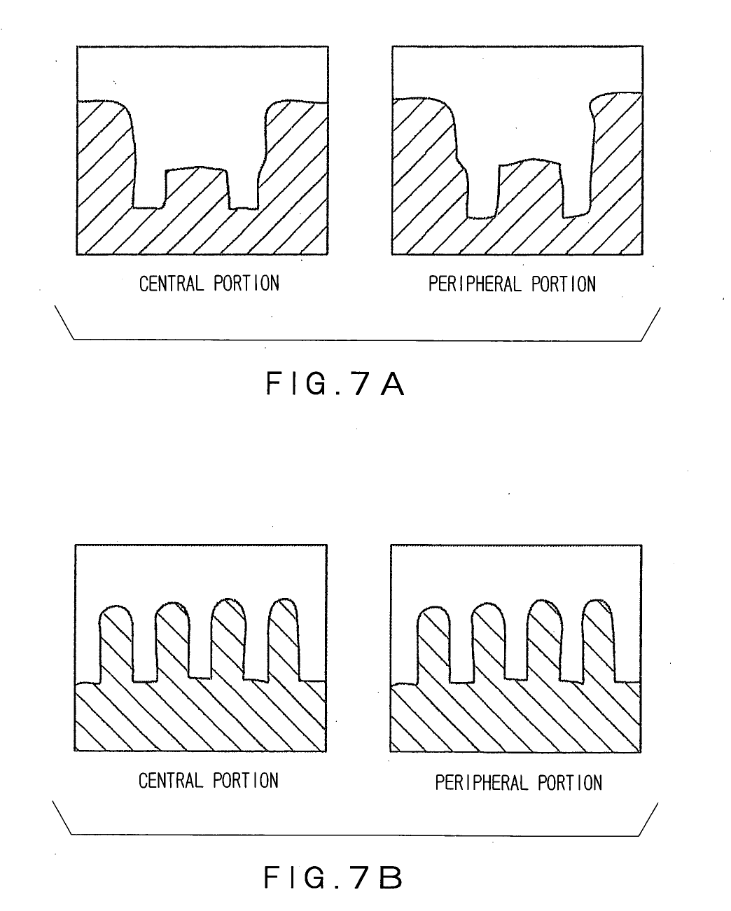

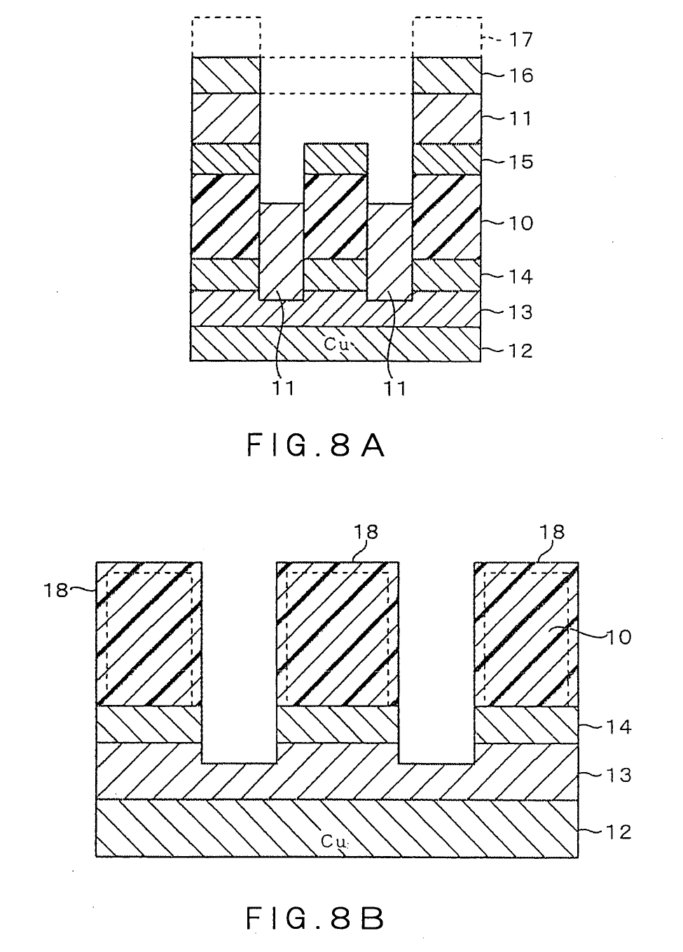

FIG. 7A and FIG. 7B are views obtained by tracing tomograms of the wafer W having been subjected to processing in the step 1 and step 2 taken with an SEM (Scanning Electron Microscope). FIG. 7A shows a central portion and a peripheral portion of the wafer W in an area close to a viahole, while FIG. 7B shows a central portion and a peripheral portion of the wafer W in an area where there is no viahole. It is recognized that the viaholes formed in the central portion and the peripheral portion of the wafer W has the substantially same form. As a result, it is confirmed that the organic film 31 embedded in the porous SiCOH film 24 can be etched into a predefined form with plasma of a process gas containing the carbon dioxide gas. That is, it is understood that the recessed portion 35 can be formed into a predefined form by etching the organic film 31 embedded as a sacrifice film in the recessed portion 35 for embedding an electrode formed on the porous SiCOH film 24 into a predefined form by using plasma of a process gas containing carbon dioxide gas.

### EXPERIMENT EXAMPLE 2

An experiment was performed to check whether any damage was given the porous SiCOH film 24 by the use of plasma of carbon dioxide gas. In this experiment, plasma of carbon dioxide gas was generated in the plasma processing apparatus shown in FIG. 3, and the plasma was irradiated for 50 seconds to the porous SiCOH film 24 having the thickness of 625 nm. The porous SiCOH film 24 was immersed for 30 seconds in a fluorinated acid with the concentration of 1% by weight, and a change in weight of the porous SiCOH film 24 before and after the immersion was measured. A result of this experiment indicates that, when a cutting rate of the porous SiCOH film 24 is small, a degree of damage to the porous SiCOH film 24 is low.

In a comparative example, plasma of oxygen was generated in the plasma processing apparatus shown in FIG. 3, and the plasma was irradiated for 40 seconds to the porous SiCOH film 24 with the thickness of 625 nm. Then the porous SiCOH film 24 was immersed in the fluorinated acid solution as described above.

As a result, it was confirmed that, when plasma of carbon dioxide was irradiated to the porous SiCOH film 24, the scraping rate was substantially small, and that the porous SiCOH film 24 was little damaged by the carbon dioxide plasma.

What is claimed is:

1. A method of manufacturing a semiconductor device, the method comprising the steps of:
preparing an object to be processed including a substrate, a low dielectric constant film formed on the substrate, having recesses, being made of a material containing silicon, carbon, oxygen, and hydrogen, and an organic film formed on the low dielectric constant film so as to be embedded in the recesses: and
etching the organic film of the object to be processed by plasma of a process gas containing carbon dioxide.

2. The method of manufacturing a semiconductor device according to claim 1,
wherein the recesses of the low dielectric constant film are used to embed electrodes, and the organic film is a sacrifice film formed on the low dielectric constant film so that the organic film is embedded in the recesses that are used to embed electrodes.

3. The method of manufacturing a semiconductor device according to claim 2,
wherein the recesses are viaholes that are used to embed electrodes for connecting both wiring of an upper layer and a lower layer in a multi-layer wiring structure; and
wherein the organic film constitutes a bottom layer in a resist structure having a plurality of layers.

4. The method of manufacturing a semiconductor device according to claim 1,
wherein the process gas further contains a nitrogen gas.

5. The method of manufacturing a semiconductor device according to claim 2,
wherein the process gas further contains a nitrogen gas.

6. The method of manufacturing a semiconductor device according to claim 3,
wherein the process gas further contains a nitrogen gas.

7. The method of manufacturing a semiconductor device according to claim 1,
wherein the low dielectric constant film has a dielectric constant of 2.7 or less.

8. The method of manufacturing a semiconductor device according to claim 2,
wherein the low dielectric constant film has a dielectric constant of 2.7 or less.

9. The method of manufacturing a semiconductor device according to claim 3,
wherein the low dielectric constant film has a dielectric constant of 2.7 or less.

10. The method of manufacturing a semiconductor devices according to claim 4,
wherein the low dielectric constant film has a dielectric constant of 2.7 or less.

11. The method of manufacturing a semiconductor device according to claim 5,
wherein the low dielectric constant film has a dielectric constant of 2.7 or less.

12. The method of manufacturing a semiconductor device according to claim 6,
wherein the low dielectric constant film has a dielectric constant of 2.7 or less.

13. A plasma processing apparatus for etching a object to be processed including a substrate, a low dielectric constant film formed on the substrate, having recesses, being made of a material containing silicon, carbon, oxygen, and hydrogen, and an organic film formed on the low dielectric constant film so as to be embedded in the recesses, the plasma processing apparatus comprising:
a processing chamber;
a lower electrode which is placed in the processing cahmber and on which the object to be processed is mounted;
an upper electrode facing the lower electrode;
a gas supply system for supplying a process gas containing cabon dioxide, the process gas being used to etch an organic film of the object to be processed; and
a high-frequency power supply for applying high-frequency power between the lower electrode and the upper electrode to convert the process gas into plasma.

14. The plasma processing apparatus according to claim 13,
wherein the recesses of the low dielectric constant film are used to embed electrodes; and
wherein the organic film is a sacrifice film formed on the low dielectric constant film so that the organic film is embedded in the recesses for embedding the electrodes.

15. The plasma processing apparatus according to claim 14,
wherein the recesses are viaholes for embedding electrodes for connecting both wiring of an upper layer and a lower layer in a multi-layer wiring structure; and
wherein the organic film constitutes a bottom layer in a resist structure having a plurality of layers.

16. The plasma processing apparatus according to claim 13,
wherein the gas supply system supplies the process gas further containing a nitrogen gas.

17. The plasma processing apparatus according to claim 14,
wherein the gas supply system supplies the process gas further containing a nitrogen gas.

18. The plasma processing apparatus according to claim 15,
wherein the gas supply system supplies the process gas further containing a nitrogen gas.

19. A computer readable storage medium comprising control programs for performing the method for manufacturing a semiconductor device according to claim 1 in a plasma processing apparatus.

20. A computer readable storage medium comprising control programs for performing the method for manufacturing a semiconductor device according to claim 2 in a plasma processing apparatus.
